(19) United States
(12) Patent Application Publication
(10) Pub. No.: US 2025/0336645 A1
(43) Pub. Date: Oct. 30, 2025

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/264,096

(22) Filed: Jul. 9, 2025

Related U.S. Application Data
(63) Continuation of application No. PCT/JP2024/000185, filed on Jan. 9, 2024.

(30) Foreign Application Priority Data
Jan. 18, 2023 (JP) 2023-005812

(51) Int. Cl. H01J 37/32

(52) U.S. Cl. CPC H01J 37/32082; H01J 37/32568

(57) ABSTRACT

A plasma processing apparatus includes: a chamber; a substrate support provided inside the chamber; an emitter provided to emit an electromagnetic wave into a plasma generation space; an upper electrode provided above the plasma generation space; and a waveguide configured to supply the electromagnetic wave to the emitter, wherein the waveguide includes a resonator that provides a waveguide path, wherein the waveguide path of the resonator is partially composed of the upper electrode, and wherein the resonator includes: a first end; a second end electromagnetically coupled to the emitter and provided to cause the electromagnetic wave to resonate between the first end and the second end; and an insulating portion configured to electrically separate the upper electrode from a conductive wall of the resonator that is conductively connected with the first end.

### CROSS-REFERENCE TO RELATED APPLICATIONS

This application is a bypass continuation application of International Patent Application No. PCT/JP2024/000185 having an international filing date of Jan. 9, 2024 and designating the United States, the international application being based upon and claiming the benefit of priority from Japanese Patent Application No. 2023-005812, filed on Jan. 18, 2023, the entire contents of which are incorporated herein by reference.

### TECHNICAL FIELD

Exemplary embodiments of the present disclosure relate to a plasma processing apparatus.

### BACKGROUND

A plasma processing apparatus is used in processing a substrate. As a type of plasma processing apparatus, an apparatus that excites gas using radio frequency waves such as VHF waves or UHF waves is known. Patent Document 1 below discloses such a plasma processing apparatus. The plasma processing apparatus of Patent Document 1 includes a processing container, a stage, an upper electrode, an introducer, and a waveguide. The stage is provided inside the processing container. The upper electrode is provided above the stage with a space inside the processing container interposed between the upper electrode and the stage. The introducer is a radio frequency introducer. The introducer is provided at a lateral end of the space and extends in a circumferential direction around a central axis of the processing container. The waveguide is configured to supply radio frequency waves to the introducer. The waveguide includes a resonator that provides a waveguide path. The waveguide path of the resonator extends in the circumferential direction around the central axis and extends in a direction in which the central axis extends so as to be connected to the introducer.

### PRIOR ART DOCUMENTS

### Patent Documents

Patent Document 1: Japanese Patent Laid-Open Publication No. 2020-92031

### SUMMARY

According to one embodiment of the present disclosure, there is provided a plasma processing apparatus including: a chamber; a substrate support provided inside the chamber; an emitter provided to emit an electromagnetic wave into a plasma generation space; an upper electrode provided above the plasma generation space; and a waveguide configured to supply the electromagnetic wave to the emitter, wherein the waveguide includes a resonator that provides a waveguide path, wherein the waveguide path of the resonator is partially composed of the upper electrode, and wherein the resonator includes: a first end; a second end electromagnetically coupled to the emitter and provided to cause the electromagnetic wave to resonate between the first end and the second end; and an insulating portion configured to electrically separate the upper electrode from a conductive wall of the resonator that is conductively connected with the first end.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a plasma processing apparatus according to one exemplary embodiment.

FIG. 2 is an enlarged partial cross-sectional view illustrating a resonator and a connector of the plasma processing apparatus according to one exemplary embodiment.

FIG. 3 is an enlarged partial plan view illustrating the resonator and the connector of the plasma processing apparatus according to one exemplary embodiment.

FIG. 4 is a diagram illustrating a plasma processing apparatus according to another exemplary embodiment.

FIG. 5 is a diagram illustrating a plasma processing apparatus according to still another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Reference will now be made in detail to various embodiments, examples of which are illustrated in the accompanying drawings. In each drawing, the same or corresponding configurations are denoted by the same reference numerals.

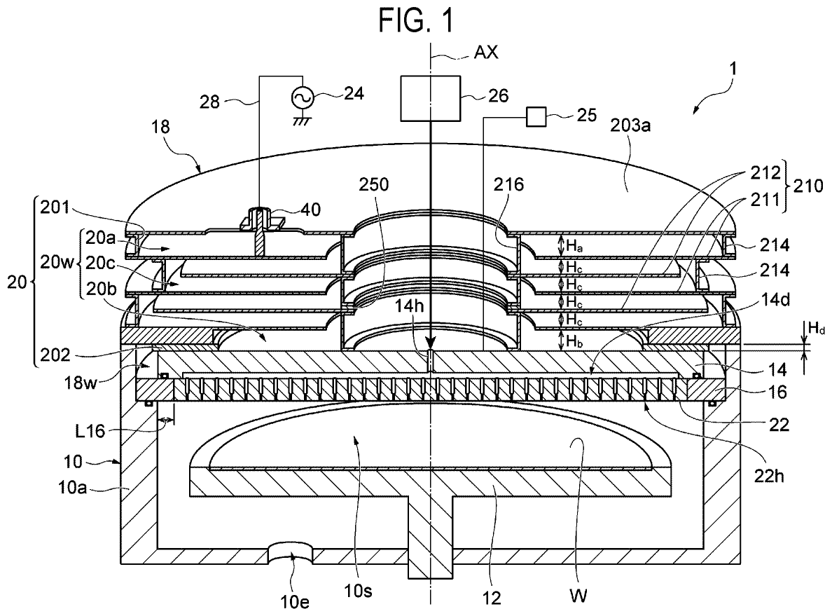

FIG. 1 is a diagram illustrating a plasma processing apparatus according to one exemplary embodiment. A plasma processing apparatus 1 illustrated in FIG. 1 includes a chamber 10, a substrate support 12, an upper electrode 14, an emitter 16, and a waveguide 18.

The chamber 10 provides a processing space 10s therein. In the plasma processing apparatus 1, a substrate W is processed within the processing space 10s. The chamber 10 is made of a metal such as aluminum and is grounded. The chamber 10 includes a sidewall 10a and is open at an upper end thereof. The chamber 10 and the sidewall 10a may have a substantially cylindrical shape. The processing space 10s is provided inside the sidewall 10a. A central axis of each of the chamber 10, the sidewall 10a, and the processing space 10s is an axis AX. The chamber 10 may include a corrosion-resistant film on a surface thereof. The corrosion-resistant film may be an yttrium oxide film, an yttrium oxide fluoride film, an yttrium fluoride film, a ceramic film including yttrium oxide or yttrium fluoride, or the like.

A bottom of the chamber 10 provides an exhaust port 10e. An exhauster is connected to the exhaust port 10e. The exhauster may include a vacuum pump, such as a dry pump and/or a turbomolecular pump, and an automatic pressure control valve.

The substrate support 12 is provided inside the processing space 10s. The substrate support 12 is configured to support the substrate W placed on an upper surface thereof in a substantially horizontal manner. The substrate support 12 has a substantially disc-like shape. A central axis of the substrate support 12 is the axis AX.

The upper electrode 14 is provided above the substrate support 12, with the processing space 10s interposed between the upper electrode 14 and the substrate support 12. The upper electrode 14 is made of a conductor such as a metal (e.g., aluminum) and has a substantially disc-like shape. A central axis of the upper electrode 14 is the axis AX.

The emitter 16 is provided to emit electromagnetic waves therefrom into a plasma generation space. In the plasma processing apparatus 1, the plasma generation space is included in the processing space 10s and a central axis thereof is the axis AX. In the plasma processing apparatus 1, the electromagnetic waves emitted from the emitter 16 into the processing space 10s excite gas existing in the processing space 10s to form plasma. The electromagnetic waves emitted from the emitter 16 into the processing space 10s may be radio frequency waves such as VHF waves or UHF waves. The emitter 16 is made of a dielectric material such as quartz, aluminum nitride, or aluminum oxide. The emitter 16 is provided at a lateral end of the processing space 10s and extends in a circumferential direction around the axis AX. The emitter 16 may have an annular shape.

The waveguide 18 is configured to supply the electromagnetic waves to the emitter 16. The electromagnetic waves are generated by a radio frequency power source 24, which is described later. The electromagnetic waves propagate to the emitter 16 via the waveguide 18 and are introduced into the processing space 10s from the emitter 16. The waveguide 18 includes a resonator 20. Details of the resonator 20 are described later.

In one embodiment, the plasma processing apparatus 1 may further include a shower plate 22. The shower plate 22 may be made of a metal such as aluminum. The emitter 16 extends to surround the shower plate 22. The emitter 16 and the shower plate 22 are disposed to close an opening at an upper end of the chamber 10. The shower plate 22 provides a plurality of gas holes 22h. The gas holes 22h extend in a thickness direction (a vertical direction) of the shower plate 22 and penetrate the shower plate 22.

The shower plate 22 is provided below the upper electrode 14. The shower plate 22 and the upper electrode 14 define a gas diffusion space 14d therebetween. A central axis of the gas diffusion space 14d may be the axis AX. The gas holes 22h of the shower plate 22 are connected to the gas diffusion space 14d. In addition, the upper electrode 14 provides an inlet 14h. The inlet 14h may extend along the axis AX. The inlet 14h is connected to the gas diffusion space 14d. A gas supply 26 is connected to the gas diffusion space 14d. Gas output from the gas supply 26 is supplied to the processing space 10s via the inlet 14h, the gas diffusion space 14d, and the gas holes 22h.

The plasma processing apparatus 1 may further include the radio frequency power source 24. The radio frequency power source 24 is electrically coupled to a waveguide path of the resonator 20 and is configured to generate radio frequency power having a variable frequency. The electromagnetic waves introduced into the chamber 10 are generated based on the radio frequency power generated by the radio frequency power source 24. The radio frequency power source 24 may be directly connected to the waveguide path of the resonator 20 by using a coaxial line 28. That is, the radio frequency power source 24 may be coupled to a waveguide path 20w of the resonator 20 without passing through a matcher for impedance matching.

The resonator 20 provides the waveguide path 20w. The waveguide path 20w may provide a cavity surrounded by a wall made of a conductor such as a metal (hereinafter, referred to as a “conductive wall”). The conductive wall of the waveguide path 20w may be made of aluminum alloy, copper, nickel, stainless steel, etc. or may be coated with a low-resistance material such as silver, gold, or rhodium.

The resonator 20 includes a first end 201 and a second end 202. The first end 201 constitutes one end of the waveguide path 20w of the resonator 20. In one embodiment, the first end 201 may extend in the circumferential direction around the axis AX.

The second end 202 constitutes the other end of the waveguide path 20w of the resonator 20. The other end of the waveguide path 20w of the resonator 20 is electromagnetically coupled to the emitter 16. In the example illustrated in FIG. 1, the other end of the waveguide path 20w of the resonator 20 is connected to the emitter 16 through a waveguide path 18w of the waveguide 18. The waveguide path 18w may be provided between the upper electrode 14 and the sidewall 10a of the chamber 10 and may extend around the axis AX. The waveguide path 18w may be filled with a dielectric material.

In the resonator 20, a fundamental wave of an electromagnetic wave having a resonant frequency is reflected at the first end 201 and the second end 202, and resonates between the first end 201 and the second end 202. In one embodiment, in order to cause the electromagnetic wave (fundamental wave) to resonate between the first end 201 and the second end 202, the second end 202 has a capacitance that shorts the waveguide path 20w at a frequency (resonant frequency) of the electromagnetic wave. In one embodiment, the second end 202 may be provided in the circumferential direction around the axis AX.

A resonator length L of the resonator 20 between the first end 201 and the second end 202 (a distance connecting the first end 201 and the second end 202 along the waveguide path 20w) may satisfy the following Equation (1).

$$n λ g / 2 < L < ( n + 0.2 ) λ g / 2 \qquad ( 1 )$$

In Equation (1), λg is the wavelength of the electromagnetic wave in the waveguide path 20w, and n is an integer. Since reactance of the second end 202 is capacitive, the resonator length L may be set to a value slightly larger than nλg/2, as expressed in Equation (1).

In one embodiment, the waveguide path 20w of the resonator 20 may include a layered structure including an upper portion 20a and a lower portion 20b. The lower portion 20b extends in a radial direction (radially outward direction) with respect to the axis AX toward the second end 202 of the resonator 20 around the axis AX. The upper portion 20a extends in a direction opposite to the radial direction (radially inward direction) from the first end 201, above the lower portion 20b and around the axis AX. That is, the upper portion 20a extends in a direction approaching the axis AX from the first end 201. The waveguide path 20w extends alternately in the radial direction and the direction opposite to the radial direction (radially outward and inward directions) so as to meander from the first end 201 to the second end 202 around the axis AX.

In one embodiment, the waveguide path 20w may further include a middle portion 20c. The middle portion 20c is provided between the upper portion 20a and the lower portion 20b. That is, the middle portion 20c is provided below the upper portion 20a and above the lower portion 20b. One end of the middle portion 20c is connected to an inner end of the upper portion 20a, i.e., an end of the upper portion 20a on an inner side with respect to the first end 201. The other end of the middle portion 20c is connected to an inner end of the lower portion 20b, i.e., to an end of the lower portion 20b on an inner side with respect to the second end 202. The middle portion 20c may extend alternately in the radial direction and the direction opposite to the radial direction so as to meander around the axis AX.

In one embodiment, the waveguide path 20w of the resonator 20 may include annular conductive plates 210, an outer periphery 214, and an inner periphery 216 in order to form the above-described layered structure. Each of the annular conductive plates 210, the outer periphery 214, and the inner periphery 216 constitutes a conductive wall of the resonator 20. In addition, the upper electrode 14 constitutes a conductive wall at a bottom of the lower portion 20b of the resonator 20.

The annular conductive plates 210 are disposed such that centers (or center axes) of the annular conductive plates 210 are located along the central axis AX. The outer periphery 214 is made of a conductor and constitutes an outer periphery of the resonator 20 in the radial direction with respect to the axis AX. The outer periphery 214 has a substantially cylindrical shape. The inner periphery 216 constitutes an inner periphery of the resonator 20 in the radial direction with respect to the axis AX. The inner periphery 216 has a substantially cylindrical shape. The inner periphery 216 is provided inside with respect to the outer periphery 214. The inner periphery 216 includes an insulating portion 250 described later. The inner periphery 216 is made of a conductor in portions other than the insulating portion 250.

In one embodiment, the annular conductive plates 210 may include one or more first annular conductive plates 211 and one or more second annular conductive plates 212. In the example illustrated in FIG. 1, the annular conductive plates 210 include a plurality of first annular conductive plates 211 and a plurality of second annular conductive plates 212.

An outer edge of each of the first annular conductive plates 211 is fixed to the outer periphery 214. An inner edge of each of the first annular conductive plates 211 is separated from the inner periphery 216. An outer edge of each of the second annular conductive plates 212 is separated from the outer periphery 214. An inner edge of each of the second annular conductive plates 212 is fixed to the inner periphery 216. The first annular conductive plates 211 and the second annular conductive plates 212 are alternately arranged in a direction in which the axis AX extends (hereinafter, referred to as a vertical direction).

In the resonator 20 including such a layered structure, a propagation direction of the electromagnetic wave having the resonant frequency includes the radial direction with respect to the axis AX and the direction opposite to the radial direction. Additionally, the propagation direction of the electromagnetic wave having the resonant frequency in the resonator 20 includes the vertical direction in an area along the inner periphery 216 and an area along the outer periphery 214.

In one embodiment, the second end 202 may be formed of a dielectric material and may be an annular plate interposed between an upper conductive wall and a lower conductive wall (the upper electrode 14 in the example of FIG. 1) that constitute the lower portion 20b. In order to cause the electromagnetic wave to resonate between the first end 201 and the second end 202, the second end 202 has an impedance lower than an impedance of the waveguide path 20w in the lower portion 20b with respect to the electromagnetic wave and, therefore, has a large capacitance. For this reason, a thickness H_{d} of the annular plate constituting the second end 202 is shorter than a length H_{b} of the lower portion 20b (or a height of the lower portion 20b) in a perpendicular direction in which the axis AX extends. Additionally, the length H_{b} is a length of the waveguide path 20w in the perpendicular direction in the lower portion 20b and is a distance between a pair of conductive walls (the upper conductive wall and the lower conductive wall) constituting the lower portion 20b in the vertical direction.

In one embodiment, the thickness H_{d} and the length H_{b} may satisfy the following Equation (2) or (3).

$$\frac{{H}_{b} \sqrt{{ε}_{r}}}{{H}_{d}} > 9 \qquad ( 2 )$$

$$\frac{{H}_{b} \sqrt{{ε}_{r}}}{{H}_{d}} > 19 \qquad ( 3 )$$

Here, εᵣ is a relative permittivity of a dielectric material constituting the second end 202.

The resonator 20 supplies the electromagnetic wave from the second end 202 of the resonator 20 to the emitter 16, and causes the electromagnetic wave to resonate between the first end 201 and the second end 202. Therefore, a reflection coefficient Γ of the second end 202 is less than 1 and has a large value close to 1. The reflection coefficient Γ is approximately expressed as Equation (4) below under the assumption that there is no reflection from below the first end 201. When an absolute value of the reflection coefficient Γ is smaller than 1 and larger than 0.8, Equation (2) is derived from Equation (4). When the absolute value of the reflection coefficient Γ is smaller than 1 and larger than 0.9, Equation (3) is derived from Equation (4).

$$Γ = \frac{\frac{{H}_{d}}{{H}_{b} \sqrt{{ε}_{r}}} - 1}{\frac{{H}_{d}}{{H}_{b} \sqrt{{ε}_{r}}} + 1} \qquad ( 4 )$$

In one embodiment, the length H_{b} may be longer than a length He of the middle portion 20c (or a height of the middle portion 20c) in a perpendicular direction. The length He is a length of the waveguide path 20w in the middle portion 20c in the perpendicular direction, and is a distance between a pair of conductive walls (an upper conductive wall and a lower conductive wall) constituting the waveguide path 20w in the middle portion 20c in the vertical direction. In this embodiment, even if the thickness H_{d} is large, the thickness H_{d} may be set to be small relative to the length H_{b}. Therefore, while setting the impedance of the second end 202 to be lower than a characteristic impedance of the waveguide path 20w in the lower portion 20b, a thickness of an annular plate constituting the second end 202 may be secured.

In one embodiment, a length L16 of an area exposed to the processing space 10s in a radial direction in the emitter 16 may be greater than the thickness H_{d}. In this case, it is possible to reduce a change in the resonant frequency of the electromagnetic wave before and after plasma ignition.

In one embodiment, the plasma processing apparatus 1 may further include a connector 40 to introduce the electromagnetic wave into the waveguide path 20w. The connector 40 is part of the coaxial line 28. The radio frequency power source 24 is coupled to the upper portion 20a through the coaxial line 28 and the connector 40. The connector 40 may be coupled to the upper portion 20a at a position separated from the axis AX in a radial direction.

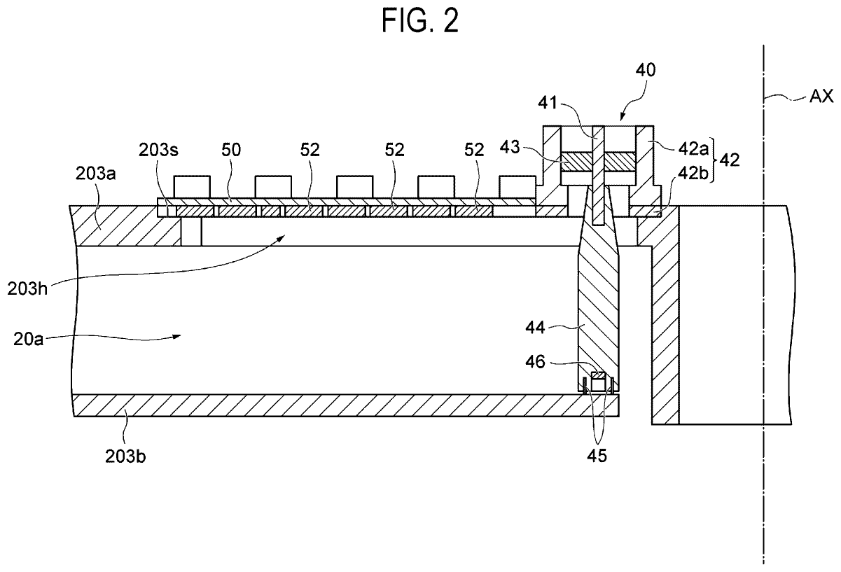

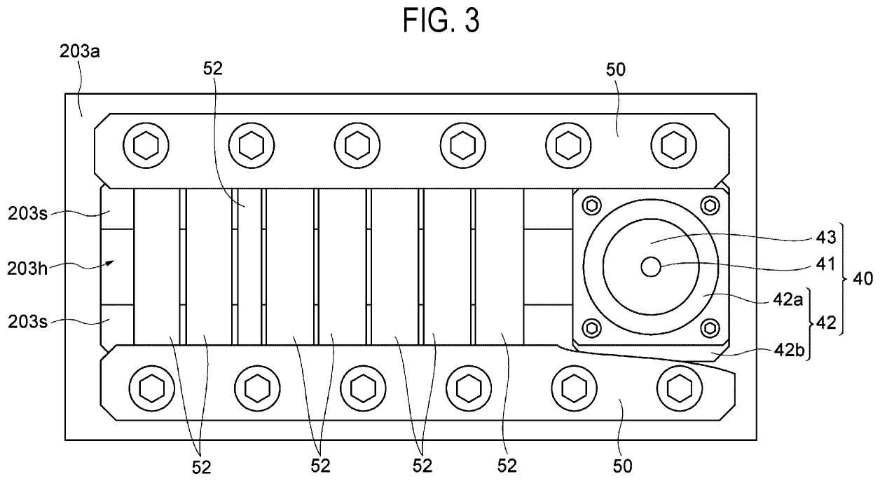

Hereinafter, an example of the structure of the connector 40 is described with reference to FIGS. 2 and 3 together with FIG. 1. FIG. 2 is an enlarged partial cross-sectional view illustrating the resonator and the connector of the plasma processing apparatus according to one exemplary embodiment. FIG. 3 is an enlarged partial plan view illustrating the resonator and the connector of the plasma processing apparatus according to one exemplary embodiment. FIG. 3 illustrates a state in which one of a pair of pressing members is partially broken.

The connector 40 is coupled to the waveguide path 20w in the upper portion 20a, as described above. The connector 40 may be configured to be movable in the radial direction with respect to the axis AX. In this case, it is possible to adjust a position at which the connector 40 is coupled to the resonator 20 to a position at which reflection of the electromagnetic wave is suppressed (e.g., a position at which there is no reflection).

In one embodiment, the connector 40 may be a coaxial connector. In this case, the connector 40 may include a center conductor 41, an outer conductor 42, a spacer 43, a coupling rod 44, and one or more contact members 45.

The center conductor 41 forms a rod shape. The center conductor 41 is electrically connected to the radio frequency power source 24. The outer conductor 42 has a cylindrical shape. The center conductor 41 is coaxial with the outer conductor 42. The spacer 43 is made of an insulating material such as polytetrafluoroethylene. The spacer 43 is interposed between the center conductor 41 and the outer conductor 42.

A through-hole 203h connected to a cavity of the upper portion 20a is formed in an upper conductive wall 203a of the upper portion 20a. The through-hole 203h extends long in the radial direction with respect to the axis AX. The upper conductive wall 203a provides support surfaces 203s on both sides of the through-hole 203h. The support surfaces 203s face upward.

The coupling rod 44 is coupled to a lower end of the center conductor 41. The coupling rod 44 extends downward via the through-hole 203h. The one or more contact members 45 are provided at a lower end of the coupling rod 44. The one or more contact members 45 may elastically contact a lower conductive wall 203b of the upper portion 20a (i.e., the first annular conductive plate 211 extending at the highest position among the plurality of first annular conductive plates 211 described later). In one embodiment, the connector 40 may include a magnet 46 incorporated into the coupling rod 44 to prevent the one or more contact members 45 from being detached from the coupling rod 44.

In one embodiment, the connector 40 may include a plurality of contact probes as the one or more contact members 45. Each of the contact probes includes a barrel, a spring disposed within an inner hole of the barrel, and a plunger that extends downward from the inner hole of the barrel and is pressurized downward by the spring. The contact probes may be arranged in a circumferential direction around a central axis of the coupling rod 44. Alternatively, the connector 40 may include a spiral spring gasket or an obliquely wound coil spring as the one or more contact members 45.

The outer conductor 42 contacts the support surface 203s. The outer conductor 42 is movable on the support surface 203s in the radial direction. Accordingly, it is possible to adjust a coupling position of the connector 40 with the upper portion 20a in the radial direction of the connector so as to suppress reflection of radio frequency power.

In a state in which the position of the connector 40 in the radial direction is set, the outer conductor 42 may be sandwiched between the support surface 203s and each of a pair of pressing members 50. Each of the pair of pressing members 50 forms, for example, a plate shape. The pair of pressing members 50 is fixed to the upper conductive wall 203a by using a plurality of bolts. In addition, in order to prevent leakage of the electromagnetic wave from the through-hole 203h, one or more covers 52 may be disposed to cover the through-hole 203h and may be sandwiched between the support surface 203s and each of the pair of pressing members 50.

In one embodiment, the outer conductor 42 may include a first member 42a and a second member 42b. The first member 42a is provided on the second member 42b, and is fixed to the second member 42b. The first member 42a has a cylindrical shape. The spacer 43 is provided between the first member 42a and the center conductor 41. The second member 42b has a plate shape and provides a through-hole that is continuous with an inner hole of the first member 42a. The second member 42b is sandwiched between the support surface 203s and each of the pair of pressing members 50.

As described above, the resonator 20 includes the insulating portion 250. The insulating portion 250 is made of an insulating material such as resin, quartz, or ceramic. The insulating portion 250 electrically separates the upper electrode 14 from the conductive wall of the resonator 20 that is conductively connected with the first end 201. In the plasma processing apparatus 1, the insulating portion 250 is an annular plate and constitutes a portion of the inner periphery 216 in the vertical direction. In the inner periphery 216, upper and lower portions of the insulating portion 250 are made of conductors.

In the plasma processing apparatus 1, the upper electrode 14 is electrically separated from the resonator 20 by the insulating portion 250. Therefore, it is possible to connect a power source different from the radio frequency power source 24 to the upper electrode 14. In one embodiment, a power source 25 is electrically connected to the upper electrode 14. The power source 25 may be a bias power source. The bias power source may be a pulse power source, a low frequency power source, a direct current power source, or the like. The power source 25 may be connected to the upper electrode 14 without passing through a filter (a filter for the frequency of the radio frequency power source 24).

In one embodiment, the length of the waveguide path 20w between the first end 201 and the insulating portion 250 may be substantially equal to ¼ of the wavelength of the electromagnetic wave (the fundamental wave having the resonant frequency) in the waveguide path 20w. In this case, a current flowing along a wall surface of the resonator 20 becomes minimum at a location at which the insulating portion 250 is provided. Therefore, in this case, leakage of the electromagnetic wave from the insulating portion 250 is suppressed. In addition, the length of the waveguide path 20w between the first end 201 and the insulating portion 250 may be greater than or less than ¼ of the wavelength of the electromagnetic wave, as long as an intensity of the electromagnetic wave leaking from the insulating portion 250 is an allowable intensity.

In one embodiment, the resonator 20 may include a structure for adjusting the length of the waveguide path 20w between the first end 201 and the insulating portion 250 to a length substantially equal to ¼ of the wavelength of the electromagnetic wave. This structure may be provided in the outer periphery 214. In the example illustrated in FIG. 1, a portion of the outer periphery 214 between the first end 201 and the insulating portion 250 may have a radius different from a radius of other portions of the outer periphery 214. In the example illustrated in FIG. 1, a radius of the outer periphery 214 in the middle portion 20c is shorter than a radius of the outer periphery 214 in each of the upper portion 20a and the lower portion 20b.

Instead of the above structure of the outer periphery 214 or in addition thereto, the structure for adjusting the length of the waveguide path 20w between the first end 201 and the insulating portion 250 to a length substantially equal to ¼ of the wavelength of the electromagnetic wave may be provided in the upper portion 20a. In the example illustrated in FIG. 1, a length Hₐ of the upper portion 20a (or a height of the upper portion 20a) in a direction in which the axis AX extends, i.e., in the perpendicular direction, is different from the lengths of other portions of the waveguide path 20w in the perpendicular direction. The length Hₐ of the upper portion 20a may be longer than the length of the other portions of the waveguide path 20w in the perpendicular direction. Specifically, the length Hₐ may be longer than the length H_{b} and the length H_{c}. In addition, the length Hₐ is a distance in the vertical direction between the pair of conductive walls (the upper conductive wall and the lower conductive wall) of the upper portion 20a. Reactance of the upper portion 20a varies depending on the length Hₐ of the upper portion 20a. Therefore, the length of the waveguide path 20w between the first end 201 and the insulating portion 250 can be adjusted depending on the length Hₐ of the upper portion 20a.

In the plasma processing apparatus 1 described above, resonance of the electromagnetic wave is promoted between the first end 201 and the second end 202. In addition, the first end 201 and the second end 202 promote uniform resonance of the electromagnetic wave in the circumferential direction. The resonated electromagnetic wave is emitted from the emitter 16 into the processing space 10s through the second end 202 of the resonator 20. Therefore, according to the plasma processing apparatus 1, plasma is efficiently generated by the electromagnetic wave resonated between the first end 201 and the second end 202.

Additionally, the second end 202 may be composed of a plurality of condensers arranged in the circumferential direction around the axis AX. In each of the condensers, one electrode of a pair of electrodes is disposed to be connected to the upper conductive wall of the lower portion 20b, and the other electrode of the pair of electrodes is disposed to be connected to the lower conductive wall of the lower portion 20b. The condensers may be disposed at equal intervals. Alternatively, the second end 202 may be composed of conductors arranged alternately with a plurality of gaps in the circumferential direction around the axis AX. Additionally, the insulating portion 250 may be configured as a portion of the outer periphery 214 rather than the inner periphery 216. A portion of the inner periphery 216 may have a radius different from a radius of other portions of the inner periphery 216.

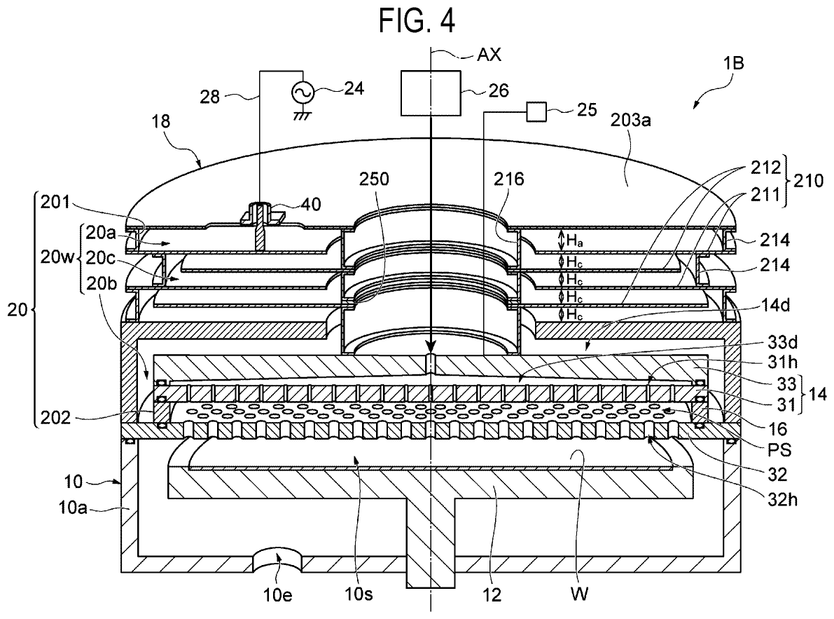

Hereinafter, a plasma processing apparatus according to another exemplary embodiment is described with reference to FIG. 4. FIG. 4 is a diagram illustrating a plasma processing apparatus according to another exemplary embodiment. Hereinafter, a plasma processing apparatus 1B illustrated in FIG. 4 is described from the viewpoint of differences from the plasma processing apparatus 1.

In the plasma processing apparatus 1B, the upper electrode 14 includes a first electrode 31 and a cover body 33. In addition, the plasma processing apparatus 1B further includes a second electrode 32.

The first electrode 31 is provided above the processing space 10s. The first electrode 31 is made of a conductor such as a metal (e.g., aluminum) and has a substantially disc shape. A central axis of the first electrode 31 is the axis AX. The first electrode 31 may provide a plurality of gas holes 31h for introducing gas into a plasma generation space PS which is described later. The gas holes 31h extend in a thickness direction (vertical direction) of the first electrode 31 and penetrate the first electrode 31.

The second electrode 32 is provided above the processing space 10s and below the first electrode 31. The second electrode 32 may extend substantially parallel to the first electrode 31. The second electrode 32 is made of a conductor such as a metal (e.g., aluminum) and has a substantially disc shape. A central axis of the second electrode 32 is the axis AX. The second electrode 32 closes the opening at the upper end of the chamber 10. That is, the second electrode 32 defines the processing space 10s from above.

The second electrode 32 provides the plasma generation space PS between the first electrode 31 and the second electrode 32. A central axis of the plasma generation space PS is the axis AX. In the plasma generation space PS, plasma is generated from gas by the electromagnetic wave emitted from the emitter 16. The second electrode 32 provides a plurality of through-holes 32h in order to guide active species from the plasma in the plasma generation space PS into the processing space 10s. The through-holes 32h extend in a thickness direction (vertical direction) of the second electrode 32 and penetrate the second electrode 32. A cross-sectional area of the through-holes 32h is configured to suppress deactivation of the active species when the active species pass through the through-holes 32h and is relatively large.

In the plasma processing apparatus 1B, the emitter 16 is configured to emit the electromagnetic wave into the plasma generation space PS in order to generate the plasma in the plasma generation space PS. The emitter 16 may extend in the circumferential direction around the axis AX so as to surround the plasma generation space PS. The emitter 16 may have a ring shape. The emitter 16 may be supported by being sandwiched between a periphery of the first electrode 31 and a periphery of the second electrode 32. In the plasma processing apparatus 1B, the electromagnetic wave propagates to the emitter 16 through the resonator 20 and is introduced from the emitter 16 into the plasma generation space PS.

The cover body 33 is provided above the first electrode 31. The cover body 33 is made of a conductor such as aluminum and has a substantially disc shape. A central axis of the cover body 33 is the axis AX.

The cover body 33 provides a gas diffusion space 33d between the first electrode 31 and the cover body 33. The gas supply 26 is connected to the gas diffusion space 33d. Gas output from the gas supply 26 is supplied to the plasma generation space PS via the gas diffusion space 33d and the gas holes 31h.

In the plasma processing apparatus 1B as well, the power source 25 is electrically connected to the upper electrode 14. As illustrated in FIG. 4, the power source 25 may be electrically connected to the cover body 33.

In the plasma processing apparatus 1B as well, the waveguide 18 includes the resonator 20. In the plasma processing apparatus 1B, the second end 202 of the resonator 20 is a boundary between the emitter 16 and the waveguide path 20w of the resonator 20.

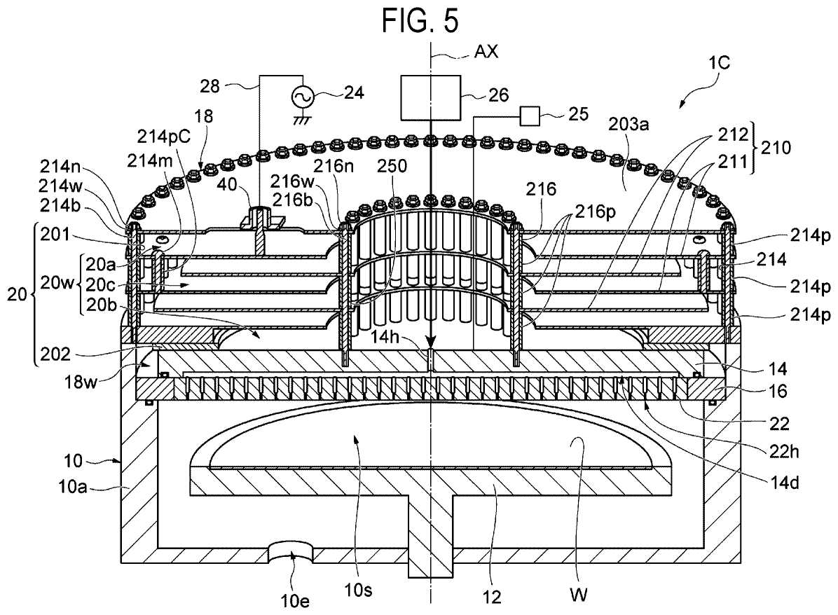

Hereinafter, a plasma processing apparatus according to another exemplary embodiment is described with reference to FIG. 5. FIG. 5 is a diagram illustrating a plasma processing apparatus according to still another exemplary embodiment. Hereinafter, a plasma processing apparatus 1C illustrated in FIG. 5 is described from the viewpoint of differences from the plasma processing apparatus 1.

In the plasma processing apparatus 1C, the outer periphery 214 includes pillars 214p. The pillars 214p are made of a conductor such as a metal. The pillars 214p extend in a direction in which the axis AX extends (i.e., the vertical direction). The pillars 214p are arranged at intervals in the circumferential direction around the axis AX. A length of a gap in the circumferential direction between any two pillars which are adjacent in the circumferential direction among the pillars 214p may be 1/100 or less of the wavelength of the electromagnetic wave (the fundamental wave having the resonant frequency) resonating in the resonator 20.

Each of the pillars 214p is divided into a plurality of portions aligned in the vertical direction. The plurality of portions of each of the pillars 214p are alternately arranged with the plurality of first annular conductive plates 211 in the vertical direction. The plurality of portions of each of the pillars 214p, the plurality of first annular conductive plates 211, and the upper conductive wall 203a are fixed so as to be conductively connected with each other.

In one embodiment, each of the plurality of portions of each of the pillars 214p has a cylindrical shape. A bolt 214b passes through the plurality of portions of each of the pillars 214p. A lower end of the bolt 214b is screwed into a screw hole formed in the first annular conductive plate 211 extending at the lowest position among the plurality of first annular conductive plates 211. An upper end of the bolt 214b is located above the upper conductive wall 203a. A nut 214n is screwed onto the upper end of the bolt 214b. The nut 214n presses the upper conductive wall 203a through a washer 214w to fix the plurality of portions of the pillars 214p, the plurality of first annular conductive plates 211, and the upper conductive wall 203a to each other.

In the plasma processing apparatus 1C, the inner periphery 216 includes pillars 216p. The pillars 216p extend in a direction in which the axis AX extends (i.e., the vertical direction). The pillars 216p are arranged at intervals in the circumferential direction around the axis AX. A length of a gap in the circumferential direction between any two pillars which are adjacent in the circumferential direction among the pillars 216p may be 1/100 or less of the wavelength of the electromagnetic wave (the fundamental wave having the resonant frequency) resonating in the resonator 20.

A portion of each of the pillars 216p in a longitudinal direction is the insulating portion 250. In each of the pillars 216p, the upper portion and the lower portion of the insulating portion 250 are made of a conductor such as a metal.

Each of the pillars 216p is divided into a plurality of portions aligned in the vertical direction. The plurality of portions of each of the pillars 216p is alternately arranged with the plurality of second annular conductive plates 212 in the vertical direction. The plurality of portions of each of the pillars 216p, the plurality of second annular conductive plates 212, and the upper conductive wall 203a are fixed so as to be conductively connected with each other.

In one embodiment, each of the plurality of portions of each of the pillars 216p has a cylindrical shape. A bolt 216b passes through the plurality of portions of each of the pillars 216p. A lower end of the bolt 216b is screwed into a screw hole formed in the upper electrode 14. An upper end of the bolt 216b is located above the upper conductive wall 203a. A nut 216n is screwed onto the upper end of the bolt 216b. The nut 216n presses the upper conductive wall 203a through a washer 216w to fix the plurality of portions of each of the pillars 216p, the plurality of second annular conductive plates 212, and the upper conductive wall 203a to each other.

In the plasma processing apparatus 1C as well, the resonator 20 may include a structure for adjusting the length of the waveguide path 20w between the first end 201 and the insulating portion 250 to a length substantially equal to ¼ of the wavelength of the electromagnetic wave. This structure may be provided at the outer periphery 214. In the example illustrated in FIG. 5, the outer periphery 214 further includes pillars 214pC. The pillars 214pC are arranged at intervals in the circumferential direction around the axis AX in the middle portion 20c. A length of a gap in the circumferential direction between any two pillars which are adjacent in the circumferential direction among the pillars 214pC may be 1/100 or less of the wavelength of the electromagnetic wave (the fundamental wave having the resonant frequency) resonating in the resonator 20. A distance between each of the pillars 214pC and the axis AX in the radial direction is shorter than a distance between each of the pillars 214p and the axis AX in the radial direction.

The pillars 214pC are held so as to be conductively connected with the two first annular conductive plates 211 in the middle portion 20c. Each of the pillars 214pC may have a cylindrical shape. In this case, each of the pillars 214pC may be fixed between the two first annular conductive plates 211 constituting the middle portion 20c by a screw 214m passing therethrough.

In addition, in the plasma processing apparatus 1C, the outer periphery 214 may be formed of a conductive wall having a substantially cylindrical shape, rather than the pillars 214p, similar to the plasma processing apparatus 1. The insulating portion 250 may be formed as a portion of the pillar 214p, rather than the pillar 216p. The pillars 214pC may be included in the inner periphery 216, rather than the outer periphery 214.

While various exemplary embodiments have been described above, the present disclosure is not limited to the above-described exemplary embodiments, and various additions, omissions, substitutions, and modifications may be made. In addition, elements in different embodiments can be combined to form other embodiments.

Various exemplary embodiments included in the present disclosure are described in [E1] to [E12] below.

[E1] A plasma processing apparatus, including:
a chamber;
a substrate support provided inside the chamber;
an emitter provided to emit an electromagnetic wave into a plasma generation space;
an upper electrode provided above the plasma generation space; and
a waveguide configured to supply the electromagnetic wave to the emitter,
wherein the waveguide includes a resonator that provides a waveguide path,
wherein the waveguide path of the resonator is partially composed of the upper electrode, and
wherein the resonator includes:
   a first end;
   a second end electromagnetically coupled to the emitter and provided to cause the electromagnetic wave to resonate between the first end and the second end; and
   an insulating portion configured to electrically separate the upper electrode from a conductive wall of the resonator that is conductively connected with the first end.

[E2] The plasma processing apparatus of E1, wherein a length of the waveguide path between the first end and the insulating portion of the resonator is substantially equal to ¼ of a wavelength of the electromagnetic wave in the waveguide path.

[E3] The plasma processing apparatus of E1 or E2, wherein the emitter extends in a circumferential direction around a central axis of the plasma generation space,
wherein the first end and the second end extend in the circumferential direction around the central axis,
wherein the first end constitutes one end of the waveguide path of the resonator and the second end constitutes the other end of the waveguide path of the resonator,
wherein the second end, which constitutes the other end of the waveguide path of the resonator, is disposed below the first end and is electromagnetically coupled to the emitter,
wherein the waveguide path of the resonator includes a layered structure including:
   a lower portion extending in a radial direction with respect to the central axis toward the second end around the central axis; and
   an upper portion extending from the first end in a direction opposite to the radial direction above the lower portion and around the central axis, and
wherein the waveguide path extends alternately in the radial direction and the direction opposite to the radial direction so as to meander from the first end to the second end around the central axis.

[E4] The plasma processing apparatus of E3, wherein the waveguide path of the resonator includes:
annular conductive plates disposed such that centers of the conductive plates are located along the central axis;
an outer periphery of the resonator in the radial direction made of a conductor; and
an inner periphery of the resonator in the radial direction, and
wherein the annular conductive plates include:
   a first annular conductive plate, an outer edge of which is fixed to the outer periphery and an inner edge of which is spaced from the inner periphery; and
   a second annular conductive plate, an outer edge of which is separated from the outer periphery and an inner edge of which is fixed to the inner periphery.

[E5] The plasma processing apparatus of E4, wherein the inner periphery includes the insulating portion which is an annular plate.

[E6] The plasma processing apparatus of E4, wherein the inner periphery includes pillars arranged in the circumferential direction around the central axis, and
wherein a portion of each of the pillars is the insulating portion.

[E7] The plasma processing apparatus of any one of E4 to E6, wherein a portion of the outer periphery between the first end and the insulating portion has a radius different from a radius of other portions of the outer periphery so as to adjust the length of the waveguide path of the resonator between the first end and the insulating portion.

[E8] The plasma processing apparatus of any one of E4 to E6, wherein a length of the upper portion in a perpendicular direction is different from a length of other portions of the waveguide path of the resonator in the perpendicular direction so as to adjust the length of the waveguide path of the resonator between the first end and the insulating portion.

[E9] The plasma processing apparatus of any one of E3 to E8, further including a connector configured to introduce the electromagnetic wave into the waveguide path of the resonator,
wherein the connector is coupled to the upper portion at a position separated from the central axis in the radial direction.

[E10] The plasma processing apparatus of any one of E1 to E9, wherein the chamber provides a processing space inside the chamber, and
wherein the processing space includes the plasma generation space.

[E11] The plasma processing apparatus of E10, further including a shower plate disposed in the processing space,
wherein the emitter extends to surround the shower plate.

[E12] The plasma processing apparatus of any one of E1 to E11, further including a radio frequency power source electrically coupled to the waveguide path of the resonator and configured to generate radio frequency power having a variable frequency and supply the electromagnetic wave into the waveguide path.

From the foregoing description, it will be understood that various embodiments of the present disclosure are described herein for purposes of illustration and that various changes may be made without departing from the scope and spirit of the present disclosure. Therefore, the various embodiments disclosed herein are not intended to be limitative, and the true scope and spirit are defined by the appended claims.

According to one exemplary embodiment, an upper electrode constituting a part of a resonator is electrically separated from the resonator.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a chamber;
a substrate support provided inside the chamber;
an emitter provided to emit an electromagnetic wave into a plasma generation space;
an upper electrode provided above the plasma generation space; and
a waveguide configured to supply the electromagnetic wave to the emitter,
wherein the waveguide includes a resonator that provides a waveguide path,
wherein the waveguide path of the resonator is partially composed of the upper electrode, and
wherein the resonator includes:
a first end;
a second end electromagnetically coupled to the emitter and provided to cause the electromagnetic wave to resonate between the first end and the second end; and
an insulating portion configured to electrically separate the upper electrode from a conductive wall of the resonator that is conductively connected with the first end.

2. The plasma processing apparatus of claim 1, wherein a length of the waveguide path between the first end and the insulating portion of the resonator is substantially equal to ¼ of a wavelength of the electromagnetic wave in the waveguide path.

3. The plasma processing apparatus of claim 2, wherein the emitter extends in a circumferential direction around a central axis of the plasma generation space,
wherein the first end and the second end extend in the circumferential direction around the central axis,
wherein the first end constitutes one end of the waveguide path of the resonator and the second end constitutes the other end of the waveguide path of the resonator,
wherein the second end, which constitutes the other end of the waveguide path of the resonator, is disposed below the first end and is electromagnetically coupled to the emitter,
wherein the waveguide path of the resonator includes a layered structure including:
a lower portion extending in a radial direction with respect to the central axis toward the second end around the central axis; and
an upper portion extending from the first end in a direction opposite to the radial direction above the lower portion and around the central axis, and
wherein the waveguide path extends alternately in the radial direction and the direction opposite to the radial direction so as to meander from the first end to the second end around the central axis.

4. The plasma processing apparatus of claim 3, wherein the waveguide path of the resonator includes:
annular conductive plates disposed such that centers of the conductive plates are located along the central axis;
an outer periphery of the resonator in the radial direction made of a conductor; and
an inner periphery of the resonator in the radial direction, and
wherein the annular conductive plates include:
a first annular conductive plate, an outer edge of which is fixed to the outer periphery and an inner edge of which is spaced from the inner periphery; and
a second annular conductive plate, an outer edge of which is separated from the outer periphery and an inner edge of which is fixed to the inner periphery.

5. The plasma processing apparatus of claim 4, wherein the inner periphery includes the insulating portion which is an annular plate.

6. The plasma processing apparatus of claim 5, wherein the chamber provides a processing space inside the chamber, and
wherein the processing space includes the plasma generation space.

7. The plasma processing apparatus of claim 6, further comprising a shower plate disposed in the processing space,
wherein the emitter extends to surround the shower plate.

8. The plasma processing apparatus of claim 4, wherein the inner periphery includes pillars arranged in the circumferential direction around the central axis, and
wherein a portion of each of the pillars is the insulating portion.

9. The plasma processing apparatus of claim 4, wherein a portion of the outer periphery between the first end and the insulating portion has a radius different from a radius of other portions of the outer periphery so as to adjust the length of the waveguide path of the resonator between the first end and the insulating portion.

10. The plasma processing apparatus of claim 4, wherein a length of the upper portion in a perpendicular direction is different from a length of other portions of the waveguide path of the resonator in the perpendicular direction so as to adjust the length of the waveguide path of the resonator between the first end and the insulating portion.

11. The plasma processing apparatus of claim 3, further comprising a connector configured to introduce the electromagnetic wave into the waveguide path of the resonator,
wherein the connector is coupled to the upper portion at a position separated from the central axis in the radial direction.

12. The plasma processing apparatus of claim 1, wherein the chamber provides a processing space inside the chamber, and
wherein the processing space includes the plasma generation space.

13. The plasma processing apparatus of claim 1, further comprising a radio frequency power source electrically coupled to the waveguide path of the resonator and configured to generate radio frequency power having a variable frequency and supply the electromagnetic wave into the waveguide path.
